(19) United States
(12) Patent Application Publication
(10) Pub. No.: US 2024/0393768 A1
(43) Pub. Date: Nov. 28, 2024

(54) SUBSTRATE PROCESSING APPARATUS, SUBSTRATE PROCESSING METHOD, AND PROGRAM

(71) Applicant: Tokyo Electron Limited, Tokyo (JP)

(72) Inventor: Rintaro TAKAO, Hokkaido (JP)

(21) Appl. No.: 18/668,767

(22) Filed: May 20, 2024

(30) Foreign Application Priority Data
May 25, 2023 (JP) 2023-085983

(51) Int. Cl. G05B 19/4155; H01L 21/67

(52) U.S. Cl. CPC G05B 19/4155; H01L 21/67155

(57) ABSTRACT

A substrate processing apparatus having a plurality of process modules for processing a processing target, includes an input unit that receives an input of recipe information indicating a processing for the processing target; and a selection unit that selects the process module for processing the processing target based on a selection rule designated by a user.

### CROSS-REFERENCE TO RELATED APPLICATIONS

This application is based on and claims priority from Japanese Patent Application No. 2023-085983 filed on May 25, 2023, with the Japan Patent Office, the disclosure of which is incorporated herein in its entirety by reference.

### TECHNICAL FIELD

The present disclosure relates to a substrate processing apparatus, a substrate processing method, and a program.

### BACKGROUND

Japanese Patent Laid-Open Publication No. 2020-113746 discloses a processing apparatus including a plurality of process modules. The processing apparatus disclosed in Patent Document 1 includes a plurality of process modules disposed to be connected, and a loader module receiving a carrier that accommodates substrates heat-treated in the plurality of process modules. Each of the plurality of process modules includes a heat treatment unit including a processing container that receives and processes a plurality of substrates, and a gas supply unit that is disposed on one side of the heat treatment unit to supply gas into the processing container.

### SUMMARY

According to one aspect of the present disclosure, there is provided a substrate processing apparatus having a plurality of process modules for processing a processing target, the substrate processing apparatus including an input unit that receives an input of recipe information indicating a processing for the processing target; and a selection unit that selects the process module for processing the processing target based on a selection rule designated by a user.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a block diagram illustrating an example of an overall configuration of a substrate processing system.

FIG. 2 is a perspective view illustrating an example of a substrate processing apparatus.

FIG. 3 is a cross-sectional view illustrating an example of the substrate processing apparatus.

FIG. 4 is a block diagram illustrating an example of a hardware configuration of a computer.

FIG. 5 is a block diagram illustrating an example of a functional configuration of the substrate processing system.

FIG. 6 is a flowchart illustrating an example of a substrate processing method.

FIG. 7 is a diagram illustrating an example of a parameter setting screen.

FIG. 8 is a diagram illustrating an example of a selection rule setting screen.

FIG. 9 is a diagram illustrating an example of a process screen.

FIG. 10 is a diagram illustrating an example of a screen for designating PM to be used.

FIG. 11 is a flowchart illustrating an example of selection processing.

FIG. 12 is a flowchart illustrating an example of selection processing.

FIG. 13 is a flowchart illustrating an example of selection processing.

FIG. 14 is a flowchart illustrating an example of selection processing.

FIG. 15 is a flowchart illustrating an example of selection processing.

FIG. 16 is a flowchart illustrating an example of selection processing.

FIG. 17 is a diagram illustrating a specific example of selection processing.

FIG. 18 is a diagram illustrating a specific example of selection processing.

### DETAILED DESCRIPTION

In the following detailed description, reference is made to the accompanying drawing, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings. In the respective drawings, the same components may be denoted by the same reference numerals, and overlapping descriptions thereof may be omitted.

### Embodiment

An embodiment of the present disclosure relates to a substrate processing system that processes a substrate, which is an example of a processing target, with a substrate processing apparatus including a plurality of process modules. Hereinafter, the process module may be referred to as “PM”.

Conventionally, in the substrate processing apparatus including a plurality of process modules, when instructing a processing for a processing target, it was possible to designate a process module to perform the processing. At this time, a user was designating the process module from various perspectives.

For example, the user may preferentially use a process module with a small number of use to equalize the number of use between process modules. For example, the user may intend to designate a process module based on a cumulative film thickness of each process module in order to efficiently perform maintenance work of the substrate processing apparatus. Also, for example, when it is determined that there is a difference in yield between process modules, the user may intend to preferentially use a process module with a good yield.

However, when the user instructs a processing, it takes effort to check use states such as the number of use or the cumulative film thickness of each process module and determine process modules based on these values. If the substrate processing apparatus may automatically select a process module desired by the user, it is possible to reduce the time for selecting the process module by the user. In one aspect, according to this embodiment, the user of the substrate processing apparatus may appropriately select a desired process module through a simple operation.

### <System Configuration>

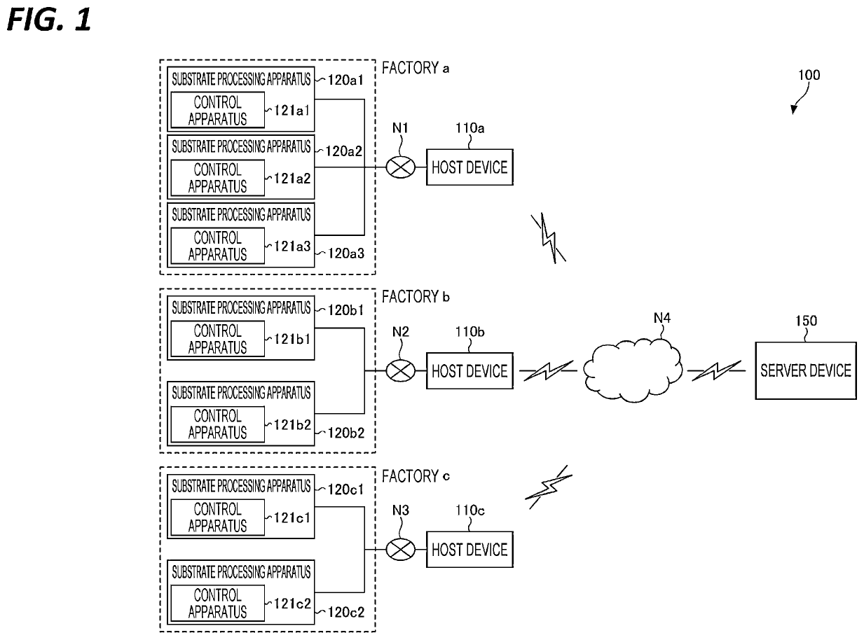

An overall configuration of the substrate processing system in this embodiment will be described with reference to FIG. 1. FIG. 1 is a block diagram illustrating an example of the overall configuration of the substrate processing system in this embodiment.

As illustrated in FIG. 1, a substrate processing system 100 includes substrate processing apparatuses 120al to 120a3 and control apparatuses 121al to 121a3 in a factory A. The substrate processing apparatuses 120al to 120a3 and the control apparatuses 121al to 121a3 are connected by a wired or wireless connection.

In addition, the substrate processing system 100 includes substrate processing apparatuses 120b1 and 120b2 and control apparatuses 121b1 and 121b2 in a factory b. The substrate processing apparatuses 120b1 and 120b2 and the control apparatuses 121b1 and 121b2 are connected by a wired or wireless connection.

In addition, the substrate processing system 100 includes substrate processing apparatuses 120c1 and 120c2 and control apparatuses 121c1 and 121c2 in a factory c. The substrate processing apparatuses 120c1 and 120c2 and the control apparatuses 121c1 and 121c2 are connected by a wired or wireless connection.

The substrate processing apparatuses 120al to 120a3, the substrate processing apparatuses 120b1 and 120b2, and the substrate processing apparatuses 121c1 and 121c2 are connected to host devices 110a, 110b, and 110c, respectively, via networks N1 to N3. Under the control of each control apparatus based on instructions from the host devices 110a, 110b, and 110c, each substrate processing apparatus executes substrate processing. The host devices 110a, 110b, and 110c are connected to a server device 150 via a network N4, such as the Internet.

In the following description, the substrate processing apparatuses 120al to 120a3, 120b1, 120b2, 120c1, and 120c2 are also collectively referred to as a substrate processing apparatus 120. In addition, the control apparatuses 121al to 121a3, 121b1, 121b2, 121c1, and 121c2 are also collectively referred to as a control apparatus 121. The host devices 110a, 110b, and 110c are also collectively referred to as a host device 110.

The substrate processing apparatuses 120al to 120a3, the substrate processing apparatuses 120b1 and 120b2, and the substrate processing apparatuses 120c1 and 120c2 store in their own devices a wide range of data that they each manage.

The substrate processing system 100 illustrated in FIG. 1 is provided by way of an example, and examples of various system configurations may be provided depending on usage or purposes. The classification of apparatuses such as the substrate processing apparatus 120, the control apparatus 121, the host device 110, and the server device 150 illustrated in FIG. 1 is provided by way of an example. For example, the number of factories, the number of host devices 110, the number of substrate processing apparatuses 120, and the number of control apparatuses 121 are provided by way of examples and are not limited thereto.

For example, the substrate processing system 100 may have various configurations such as a configuration in which at least two of the substrate processing apparatus 120, the control apparatus 121, the host device 110, and the server device 150 are integrated or separated. For example, the control apparatus 121 may control a plurality of substrate processing apparatuses 120 in an integrated manner, or may be provided one to one for the substrate processing apparatus 120, or may be integrated with the substrate processing apparatus 120.

### <Substrate Processing Apparatus>

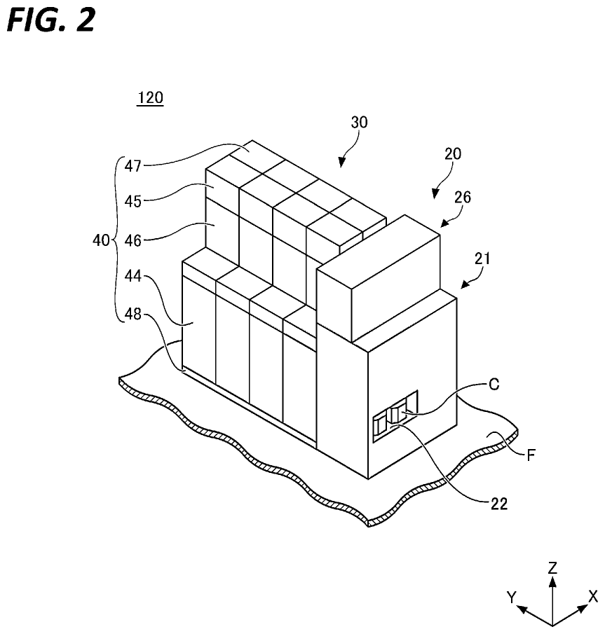

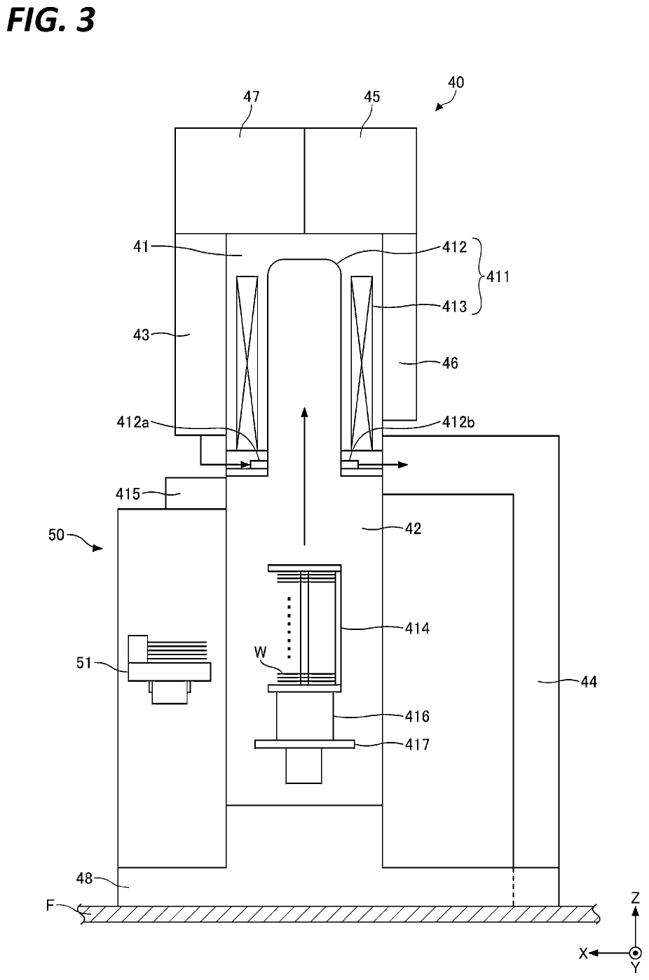

An example of the substrate processing apparatus according to this embodiment will be described with reference to FIGS. 2 and 3. FIG. 2 is a perspective view illustrating an example of the substrate processing apparatus in this embodiment. FIG. 3 is a cross-sectional view illustrating an example of the substrate processing apparatus. Hereinafter, a left-right direction of the substrate processing apparatus will be described as an X-direction, a front-rear direction of the substrate processing apparatus will be described as a Y-direction, and a height direction of the substrate processing apparatus will be described as a Z-direction.

As illustrated in FIG. 2, the substrate processing apparatus 120 includes a loader module 20 and a processing module 30.

An inside of the loader module 20 is under, for example, an atmospheric condition. The loader module 20 is an area in which a carrier C having a semiconductor wafer (hereinafter, referred to as a “wafer W”) accommodated therein, which is an example of a substrate, is transferred between elements (which will be described later) within the substrate processing apparatus 120, is carried into the substrate processing apparatus 120 from the outside, or is carried out to the outside from the substrate processing apparatus 120. The carrier C may be, for example, a front-opening unified pod (FOUP). The loader module 20 includes a first transfer unit 21 and a second transfer unit 26 located behind the first transfer unit 21.

In the first transfer unit 21, two load ports 22 are provided on left and right sides thereof by way of an example. The load port 22 is a stage for receiving the carrier C when the carrier C is carried into the substrate processing apparatus 120. The load port 22 is provided in a location where a wall of a case portion is open, and may access the substrate processing apparatus 120 from the outside. The first transfer unit 21 is provided with one or more stockers (not illustrated) to store the carrier C.

A FIMS port (not illustrated) is disposed on the second transfer unit 26. For example, two FIMS ports are provided and disposed vertically. The FIMS port is a holding stand that holds the carrier C when carrying the wafer W within the carrier C into and out of a heat treatment furnace 411 within the processing module 30, which will be described later. The FIMS port may move in the front-rear direction. Also, similar to the first transfer unit 21, the second transfer unit 26 is also provided with one or more stockers (not illustrated) to store the carrier C.

Between the first transfer unit 21 and the second transfer unit 26, a carrier transfer mechanism (not illustrated) is provided to transfer the carrier C between the load port 22, the stocker, and the FIMS port.

The processing module 30 is a module that extracts the wafer W from the carrier C and performs various processings on the wafer W. An inside of the processing module 30 is under an inert gas atmosphere, such as a nitrogen gas atmosphere, to prevent an oxide film from being formed on the wafer W. The processing module 30 includes four process modules 40, and a wafer transfer module 50.

The process modules 40 are disposed to be connected in the front-rear direction. Each process module 40 includes a heat treatment unit 41, a load unit 42, a gas supply unit 43, an exhaust duct 44, an RCU unit 45, a sorting duct 46, a control unit 47, and a floor box 48.

As illustrated in FIG. 3, the heat treatment unit 41 is a unit that accommodates a plurality (for example, 25 to 150 sheets) of wafers W and performs a predetermined heat treatment. The heat treatment unit 41 includes the heat treatment furnace 411.

The heat treatment furnace 411 includes a processing container 412 and a heater 413.

The processing container 412 accommodates a wafer boat 414. The wafer boat 414 has a cylindrical shape made of, for example, quartz, and holds a plurality of wafers W in multiple stages. The processing container 412 is provided with a gas introduction port 412a and an exhaust port 412b.

The gas introduction port 412a is a port for introducing gas into the processing container 412. The gas introduction port 412a is disposed next to the gas supply unit 43. In addition, a location where the gas introduction port 412a is provided is the same in a plurality of the process modules 40.

The exhaust port 412b is a port that exhausts gas in the processing container 412. The exhaust port 412b is disposed next to the exhaust duct 44. In addition, a location where the exhaust port 412b is provided is the same in the plurality of process modules 40.

The heater 413 is provided around the processing container 412 and has a cylindrical shape, for example. The heater 413 heats the wafer W accommodated in the processing container 412. A shutter 415 is provided below the processing container 412. The shutter 415 is a door for covering a bottom of the heat treatment furnace 411 while the wafer boat 414 is carried out from the heat treatment furnace 411 and the next wafer boat 414 is carried therein.

The load unit 42 is disposed below the heat treatment unit 41 and is installed on a floor F through the floor box 48. In the load unit 42, the wafer boat 414 is disposed on a cover portion 417 through a heat insulation tank 7. The wafer boat 414 is formed of a heat-resistant material, such as quartz or silicon carbide, and holds the wafers W approximately horizontally with predetermined intervals in a vertical direction. The cover portion 417 is supported on a lifting mechanism (not illustrated), and the wafer boat 414 is carried in and out from the processing container 412 by the lifting mechanism. The load unit 42 also functions as a space for cooling the processed wafers W in the heat treatment unit 41.

The gas supply unit 43 is disposed on a side surface of the heat treatment unit 41 to be spaced apart from the floor F. The gas supply unit 43 is disposed to overlap, for example, the wafer transfer module 50, as viewed in a plan view. The gas supply unit 43 includes a pressure regulator, a mass flow controller, and a valve to supply a predetermined flow amount of processing gas or purge gas into the processing container 412.

The exhaust duct 44 is disposed to face the gas supply unit 43 with the heat treatment unit 41 interposed therebetween. The exhaust duct 44 includes an exhaust pipe that connects a vacuum pump (not illustrated) with an inside of the processing container 412, and a pipe heater that heats the exhaust pipe.

The RCU unit 45 is disposed on a ceiling of the heat treatment unit 41. The RCU unit 45 is a unit for generating refrigerants that are supplied to the sorting duct 46, and includes a heat exchanger, a blower, a valve and a pipe.

The sorting duct 46 is provided on the side surface of the heat treatment unit 41, for example, at a position facing the gas supply unit 43 with the heat treatment unit 41 interposed therebetween. The sorting duct 46 sorts the refrigerants sent from the RCU unit 45 and supplies them to a space between the processing container 412 and the heater 413. Accordingly, it is possible to cool the processing container 412 in a short time.

The control unit 47 is disposed on the ceiling of the heat treatment unit 41. The control unit 47 includes a control mechanism for controlling an operation of each unit of the process module 40. The control mechanism may control, for example, an operation of the gas supply unit 43 to adjust a flow rate of the processing gas or purge gas supplied to the processing container 412.

The wafer transfer module 50 is an example of a substrate transfer module, and a single wafer transfer module 50 is provided in common for the plurality of process modules 40. In other words, the plurality of process modules 40 have a common wafer transfer module 50. The wafer transfer module 50 is disposed across one side of the plurality of process modules 40 and is installed on the floor F through the floor box 48. The wafer transfer module 50 is provided with a wafer transfer mechanism 51, which is an example of a substrate transfer mechanism. The wafer transfer mechanism 51 transfers the wafers W between the carrier C disposed in the FIMS port and the wafer boat 414 disposed in the load unit 42 of the process module 40. The wafer transfer mechanism 51 may have, for example, a plurality of forks and may transfer the plurality of wafers W simultaneously. Accordingly, it is possible to shorten the time required for transferring the wafers W. However, a single fork may be provided.

### <Hardware Configuration>

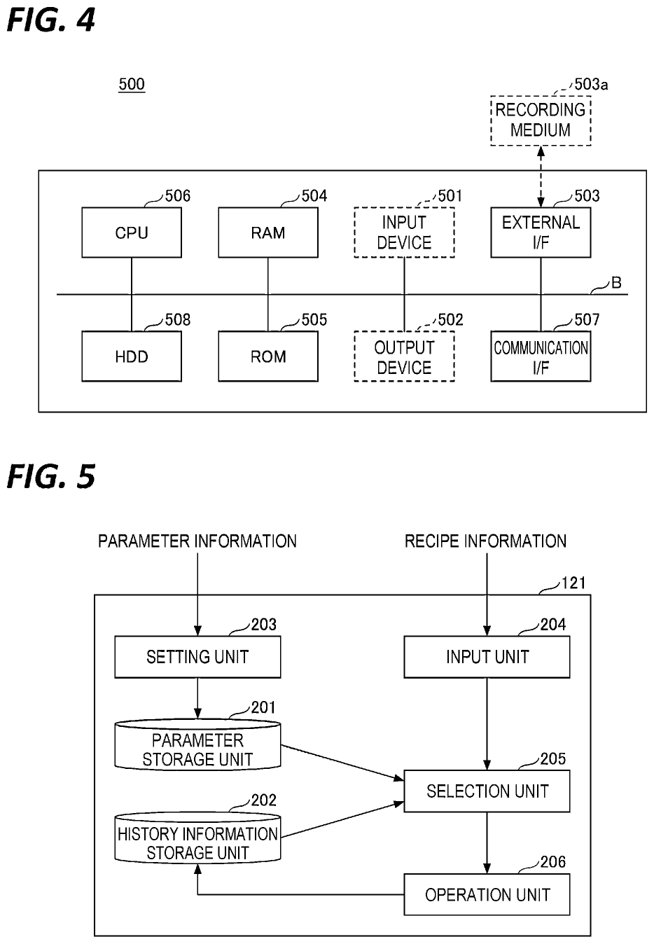

The host device 110, the control apparatus 121, and the server device 150 included in the substrate processing system 100 illustrated in FIG. 1 are implemented by a computer with a hardware configuration such as that illustrated in FIG. 4, for example. FIG. 4 is a block diagram illustrating an example of a hardware configuration of a computer in this embodiment.

As illustrated in FIG. 4, a computer 500 of this embodiment includes an input device 501, an output device 502, an external I/F (interface) 503, a random access memory (RAM) 504, a read only memory (ROM) 505, a central processing unit (CPU) 506, a communication I/F 507, and a hard disk drive (HDD) 508, each of which is connected by a bus B. Further, the input device 501 and the output device 502 may be connected and used as needed.

The input device 501 is a keyboard, a mouse, or a touch panel and is used to input each operational signal by an operator. The output device 502 is a display or the like, and displays a result of processing by the computer 500. The communication I/F 507 is an interface that connects the computer 500 to the network. The HDD 508 is an example of a non-volatile storage device that stores programs or data.

The external I/F 503 is an interface to an external device. The computer 500 may perform reading and/or recording on a recording medium 503a, such as a secure digital (SD) memory card, via the external I/F 503. The ROM 505 is an example of a non-volatile semiconductor memory (storage device) in which programs or data are stored. The RAM 504 is an example of a volatile semiconductor memory (storage device) that temporarily holds programs or data.

The CPU 506 is a computing device that reads programs or data from the storage device such as the ROM 505 or the HDD 508 and executes a processing to implement control or functions of the entire computer.

### <Functional Configuration>

A functional configuration of the control apparatus in this embodiment will be described with reference to FIG. 5. FIG. 5 is a diagram illustrating an example of a functional configuration of the control apparatus in this embodiment.

### <<Control Apparatus>>

As illustrated in FIG. 5, the control apparatus 121 of this embodiment includes a parameter storage unit 201, a history information storage unit 202, a setting unit 203, an input unit 204, a selection unit 205, and an operation unit 206.

The parameter storage unit 201 and the history information storage unit 202 are implemented, for example, by the RAM 504 or HDD 508 illustrated in FIG. 4. The setting unit 203, the input unit 204, the selection unit 205, and the operation unit 206 are implemented by, for example, the CPU 506 illustrated in FIG. 4, executing a program loaded on the RAM 504.

In the parameter storage unit 201, parameter information indicating various parameters set in the substrate processing apparatus 120 is stored. The parameter information includes parameters that set selection rules for selecting process modules.

The history information storage unit 202 stores history information indicating the history of executing a processing on the processing target by the substrate processing apparatus 120. The history information includes information indicating a use state of each process module.

The information indicating the use state includes the number of use and a cumulative film thickness. The number of use is the number of times a processing has been executed in the process module. The cumulative film thickness is a cumulative value of film thicknesses processed by the process module. In addition, the information indicating the use state may be reset to an initial value such as 0 times or 0 nm when cleaning is performed in the process module.

The setting unit 203 receives an input of parameter information. The setting unit 203 sets values for the parameters stored in the parameter storage unit 201 based on the input parameter information.

The parameter information may be input by the user through a screen displayed on a display provided in the substrate processing apparatus 120. The parameter information may be input to the substrate processing apparatus 120 by receiving a message in which parameter information input to the host device 110 is set.

The input unit 204 receives an input of recipe information. The recipe information is information indicating a processing to be executed on a processing target. The recipe information may be a work recipe that includes a plurality of processings whose processing order is defined. The processings include, for example, heat treatment such as a film formation processing or an etching processing. The recipe information includes information indicating the process module designated by the user. The information indicating the process module may be information designating a specific process module, or may be information designating automatic selection of a process module.

The recipe information may be input by the user through a screen displayed on the display provided in the substrate processing apparatus 120. The recipe information may be input to the substrate processing apparatus 120 by receiving a message in which the recipe information input to the host device 110 is set.

The selection unit 205 selects a process module to execute the processing indicated in the recipe information input to the input unit 204. When a specific process module is designated in the recipe information, the selection unit 205 selects the process module. Meanwhile, when the recipe information designates that a process module is automatically selected, the selection unit 205 selects a process module to be used among usable process modules according to the selection rule designated in the parameter information.

The operation unit 206 operates the substrate processing apparatus 120 such that the processing indicated in the recipe information input to the input unit 204 is executed in the process module selected by the selection unit 205. The operation unit 206 stores history information indicating the history of the processing executed in the process module, in the history information storage unit 202.

### <Selection Rules>

In this embodiment, the selection rules include a PM priority, an order of smaller cumulative film thicknesses, an order of larger cumulative film thicknesses, an order of fewer numbers of use, and an order of greater numbers of use. These selection rules are provided by way of example, and other selection rules may be included therein according to the needs of the user.

The PM priority is a selection rule that prioritizes and selects process modules with higher priorities set by the user for each process module. For example, when the substrate processing apparatus 120 has four process modules PM1 to PM4, and a priority of PM1→PM3→PM2→PM4 is set, it is determined whether the process module is usable in the order of PM1→PM3-PM2→PM4, and if the process module is usable, the processing is executed in the process module.

The order of smaller cumulative film thicknesses is a rule that prioritizes and selects process modules with smaller cumulative film thicknesses. For example, when the cumulative film thickness is larger in the order of PM1→PM3→PM2→PM4, it is determined whether the process module is usable in the order of PM1→PM3→PM2→PM4, and if the process module is usable, the processing is executed in the process module.

The order of larger cumulative film thicknesses is a rule that prioritizes and selects process modules with larger cumulative film thicknesses. For example, when the cumulative film thickness is larger in the order of PM1→PM3→PM2→PM4, it is determined whether the process module is usable in the order of PM4→PM2→PM3→PM1, and if the process module is usable, the processing is executed in the process module.

The order of the fewer numbers of use is a rule that prioritizes and selects process modules with fewer numbers of use. For example, when the number of use is greater in the order of PM1→PM3→PM2→PM4, it is determined whether the process module is usable in the order of PM1→PM3→PM2→PM4, and if the process module is usable, the processing is executed in the process module.

The order of greater numbers of use is a rule that prioritizes and selects process modules with greater numbers of use. For example, when the number of use is greater in the order of PM1→PM3→PM2→PM4, it is determined whether the process module is usable in the order of PM4→PM2→PM3→PM1, and if the process module is usable, the processing is executed in the process module.

In the selection rules (i.e., the order of smaller cumulative film thicknesses, the order of larger cumulative film thicknesses, the order of fewer numbers of use, and the order of greater numbers of use) regarding the use state, if there are multiple process modules with the same value, it is possible to select a process module to be used from among the process modules with the same value, according to a predetermined criterion. The predetermined criterion may be, for example, a distance from the FIMS (e.g., in the order of being closer to the FIMS).

### <Processing Order>

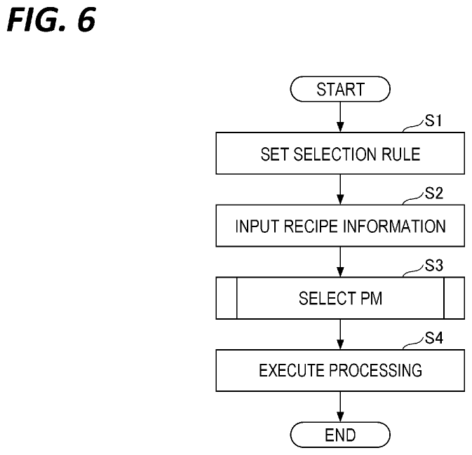

A substrate processing method executed by the substrate processing system 100 in this embodiment will be described with reference to FIGS. 6 to 10. FIG. 6 is a flow diagram illustrating an example of a substrate processing method in this embodiment.

In step S1, the setting unit 203 of the control apparatus 121 receives an input of parameter information for setting the selection rule. The setting unit 203 may receive the input of the parameter information through a parameter setting screen displayed on the display provided in the substrate processing apparatus 120. The setting unit 203 may receive parameter information set in a message received from the host device 110.

### <<Parameter Setting Screen>>

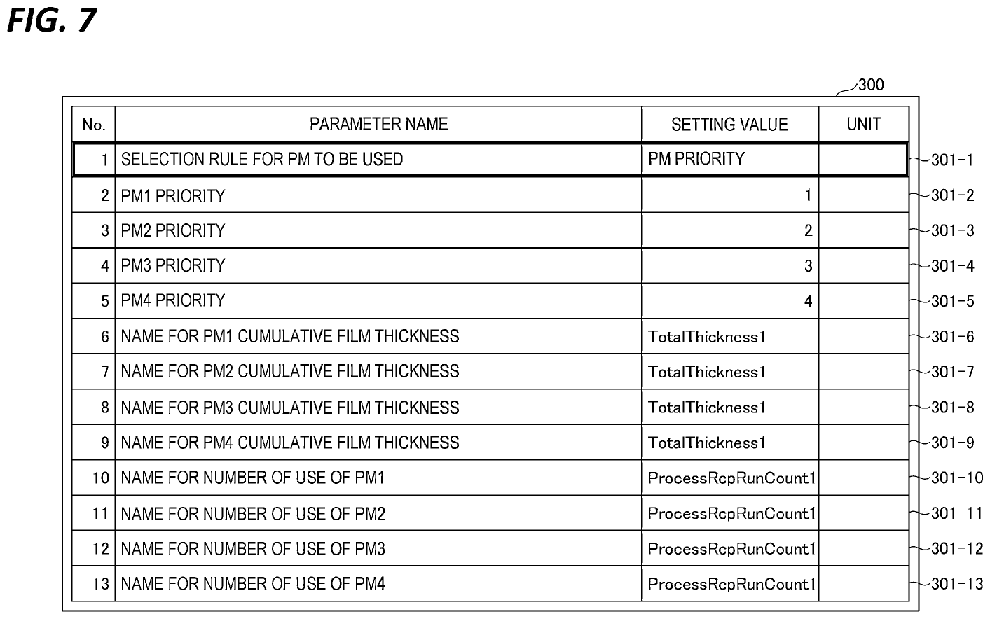

The parameter setting screen in this embodiment will be described with reference to FIG. 7. FIG. 7 is a diagram illustrating an example of a parameter setting screen.

As illustrated in FIG. 7, a parameter setting screen 300 includes a plurality of parameter setting sections 301 (301-1 to 301-13). Each parameter setting section 301 includes data items such as item number (No.), parameter name, setting value, and unit.

The plurality of parameter setting sections 301 include the parameter setting section 301-1 corresponding to the selection rule. In this embodiment, the name of a parameter indicating the selection rule is “selection rule for PM to be used (hereinafter, referred to as “PM selection rule”).

When the user performs an operation (e.g., double-clicking or pressing the Enter key) to start the parameter setting section 301-1, a selection rule setting screen is displayed. The selection rule setting screen is a screen for selecting the selection rule to be set as the “PM selection rule”.

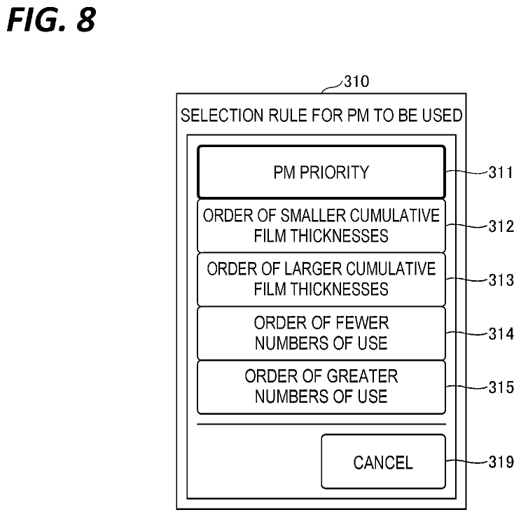

FIG. 8 is a diagram illustrating an example of a selection rule setting screen. As illustrated in FIG. 8, a selection rule setting screen 310 includes five selection buttons 311 to 315 and a cancellation button 319. The number of selection buttons in the selection rule setting screen 310 is equal to the number of the selection rules.

When the user presses the selection button 311, the selection rule is set to “PM priority”. When the user presses the selection button 312, the selection rule is set to “the order of smaller cumulative film thicknesses.” When the user presses the selection button 313, the selection rule is set to “the order of larger cumulative film thicknesses”. When the user presses the selection button 314, the selection rule is set to “the order of fewer numbers of use.” When the user presses the selection button 315, the selection rule is set to “the order of greater numbers of use.”

When the user presses the cancellation button 319, a selection rule is not set, and the previous selection rule is maintained. An initial value of the selection rule may be determined arbitrarily, but may be set to “PM priority”, for example.

The setting unit 203 sets the parameters stored in the parameter storage unit 201 based on the received parameter information. Specifically, the setting unit 203 sets the selection rule selected by the user to “PM selection rule” of the parameter stored in the parameter storage unit 201.

Referring back to FIG. 6, descriptions will be made. In step S2, the input unit 204 of the control apparatus 121 receives the input of the recipe information. The input unit 204 may receive the input of the recipe information through a process screen displayed on the display provided in the substrate processing apparatus 120. The input unit 204 may receive recipe information set in a message received from the host device 110. The input unit 204 sends the received recipe information to the selection unit 205.

### <<Process Screen>>

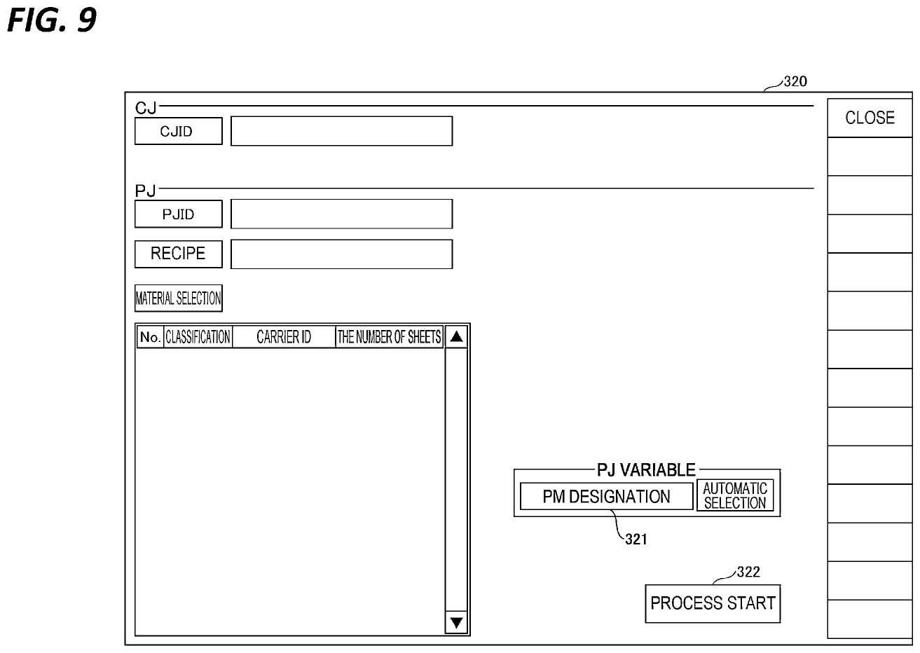

The process screen in this embodiment will be described with reference to FIG. 9. FIG. 9 is a diagram illustrating an example of the process screen.

As illustrated in FIG. 9, a process screen 320 includes a button 321 for designating PM to be used (hereinafter, referred to as “PM designation button 321”) and a process start button 322. When the user presses the PM designation button 321, a screen for designating PM to be used (hereinafter, referred to as “PM designation screen”) is displayed. The PM designation screen is a screen for designating a process module to execute the processing included in the work recipe.

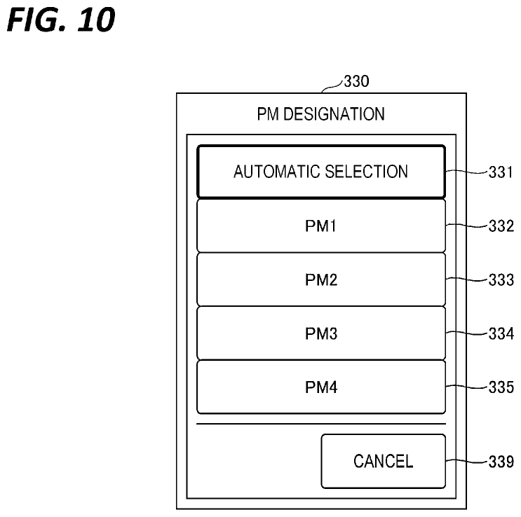

FIG. 10 is a diagram illustrating an example of a PM designation screen. As illustrated in FIG. 10, a PM designation screen 330 includes an automatic selection button 331, four designation buttons 332 to 335, and a cancellation button 339. The number of designation buttons in the PM designation screen 330 is equal to the number of the process modules in the substrate processing apparatus 120.

When the user presses the automatic selection button 331, selecting a process module according to the selection rule that has been set is set as the recipe information. The selection rule to be used is the selection rule set as “PM selection rule”.

When the user presses the designation button 332, selecting the process module PM1 is set as the recipe information. Similarly, when the user presses the designation button 333, 334, or 335, selecting each process module PM2, PM3, or PM4 is set as the recipe information.

When the user presses the cancellation button 339, a process module to be used is not designated, and the previous setting is maintained. Also, an initial value for designating PM to be used may be arbitrarily determined, such as “automatic selection”.

Referring back to FIG. 6, descriptions will be made. In step S3, the selection unit 205 of the control apparatus 121 receives the recipe information from the input unit 204. Next, the selection unit 205 selects a process module to execute the processing indicated in the recipe information.

If there is only one process module usable, the selection unit 205 selects the process module. Meanwhile, if there are multiple process modules usable, the selection unit 205 executes selection processing. The selection processing is a processing of selecting a process module according to a selection rule. The selection unit 205 sends information indicating the selected process module to the operation unit 206.

### <<Selection Processing>>

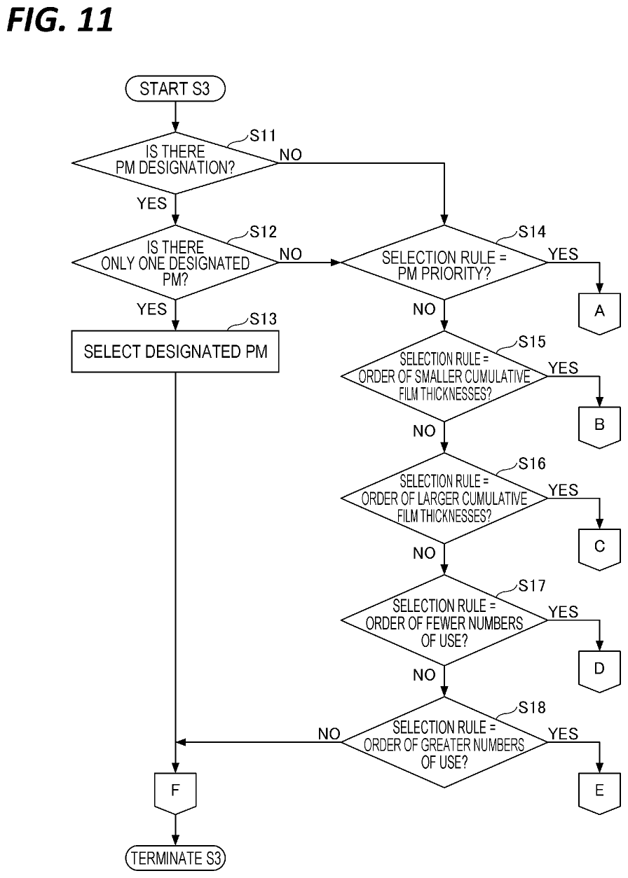

The selection processing in this embodiment will be described with reference to FIGS. 11 to 16. FIGS. 11 to 16 are flow diagrams illustrating an example of selection processing. The selection processing is executed by the selection unit 205 of the control apparatus 121.

In step S1, the selection unit 205 determines whether a specific process module is designated in the recipe information. When the specific process module is designated (YES), the processing proceeds to step S12 by the selection unit 205. In the meantime, when the specific process module is not designated (NO), the processing proceeds to step S14 by the selection unit 205. A case where a specific process module is not designated includes a case where “automatic selection” is selected on the process screen 320.

In step S12, the selection unit 205 determines whether there is only one process module designated in the recipe information. When the designated process module is a single process module (YES), the processing proceeds to step S13 by the selection unit 205. Meanwhile, when the designated process module is a plurality of process modules (NO), the processing proceeds to step S14 by the selection unit 205.

In step S13, the selection unit 205 selects the process module designated in the recipe information.

In step S14, the selection unit 205 reads the selection rule from the parameter storage unit 201. Specifically, the selection unit 205 reads a value set as “PM selection rule” from the parameter stored in the parameter storage unit 201.

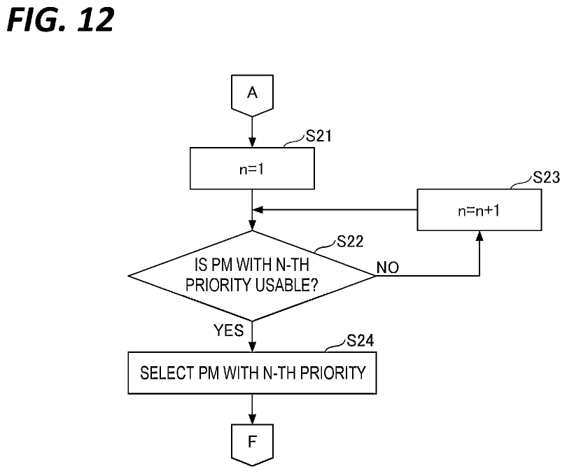

Next, the selection unit 205 determines whether the selection rule is “PM priority”. When the selection rule is “PM priority” (YES), the processing proceeds to step S21 (see FIG. 12) by the selection unit 205. Meanwhile, when the selection rule is not “PM priority” (NO), the processing proceeds to step S15 by the selection unit 205.

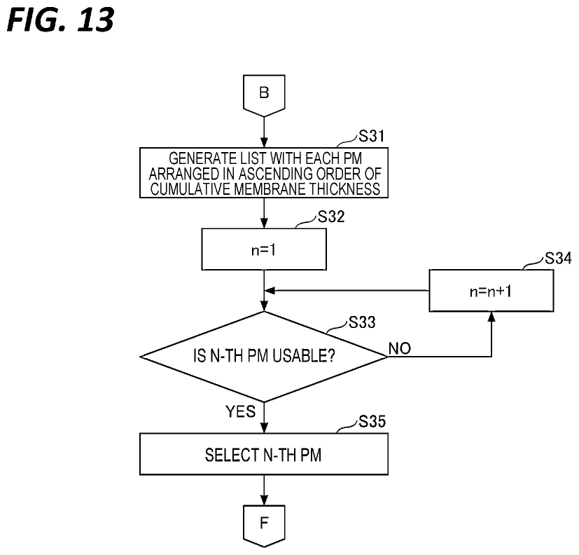

In step S15, the selection unit 205 determines whether the selection rule is “the order of smaller cumulative film thicknesses”. When the selection rule is “the order of smaller cumulative film thicknesses” (YES), the processing proceeds to step S31 (see FIG. 13) by the selection unit 205. Meanwhile, when the selection rule is not “smaller cumulative film thicknesses” (NO), the processing proceeds to S16 by the selection unit 205.

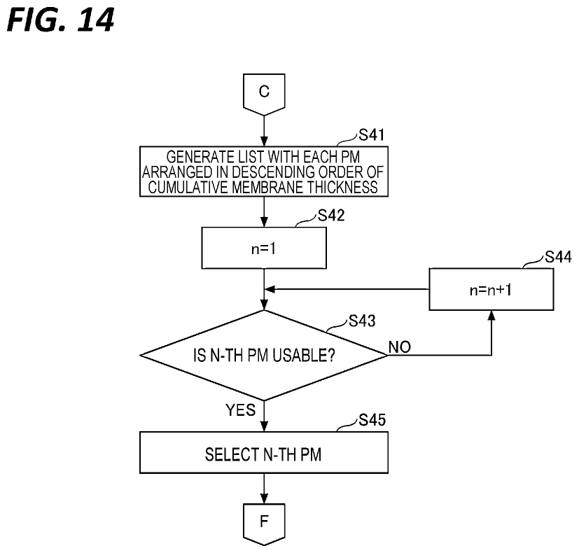

In step S16, the selection unit 205 determines whether the selection rule is “the order of the larger cumulative film thicknesses”. When the selection rule is “the order of the larger cumulative film thicknesses” (YES), the processing proceeds to step S41 (see FIG. 14) by the selection unit 205. Meanwhile, when the selection rule is not “the order of the larger cumulative film thicknesses” (NO), the processing proceeds to step S17 by the selection unit 205.

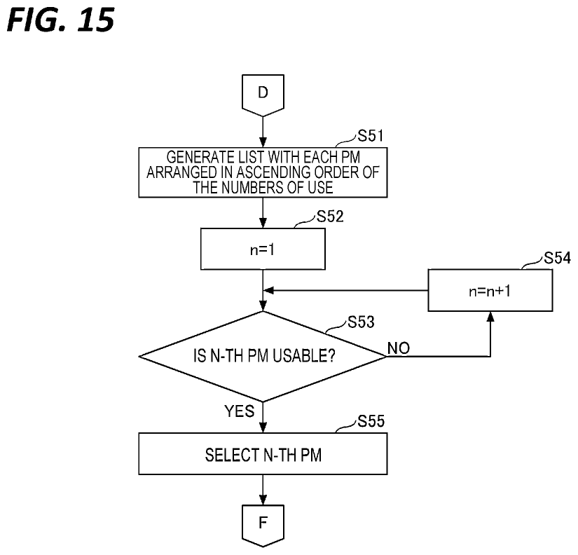

In step S17, the selection unit 205 determines whether the selection rule is “the order of fewer numbers of use”. When the selection rule is “the order of fewer numbers of use” (YES), the processing proceeds to step S51 (see FIG. 15) by the selection unit 205. Meanwhile, when the selection rule is not “the order of fewer numbers of use” (NO), the processing proceeds to step S18 by the selection unit 205.

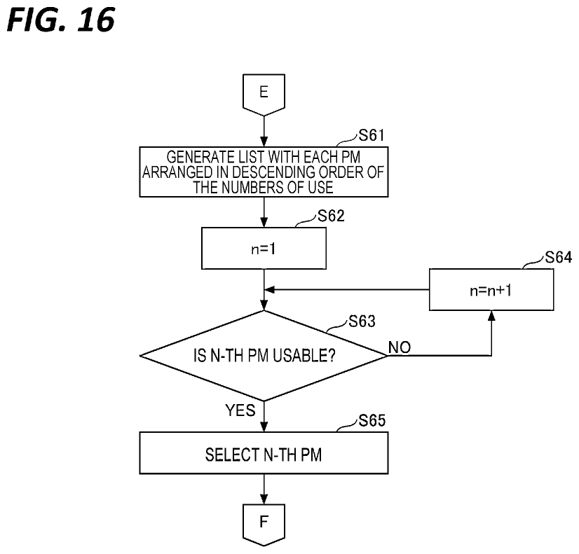

In step S18, the selection unit 205 determines whether the selection rule is “the order of greater numbers of use”. When the selection rule is “the order of greater numbers of use” (YES), the processing proceeds to step S61 (see FIG. 16) by the selection unit 205. Meanwhile, when the selection rule is not “the order of greater numbers of use” (NO), the selection unit 205 does not select the process module and terminates the selection processing. However, a state in which automatic selection is designated in the recipe information and no selection rules are set may not normally occur.

Referring to FIG. 12, descriptions will be made. In step 521, the selection unit 205 initializes an index n to 1. The index n is a number indicating a sequence of the process modules.

In step 522, the selection unit 205 determines whether a process module with an n-th priority is usable. Further, the priority of each process module is designated in the parameter setting screen 300.

When the selection unit 205 determines that the process module with the n-th priority is usable (YES), the processing proceeds to S24 by the selection unit 205. Meanwhile, when it is determined that the process module with the n-th priority is not usable (NO), the processing proceeds to step S23 by the selection unit 205.

In step S23, the selection unit 205 increments the index n, i.e., calculates n=n+1. Thereafter, the selection unit 205 returns the processing to step S22 and determines whether the process module with the n-th priority is usable.

In step S24, the selection unit 205 selects the process module with the n-th priority. Then, the selection unit 205 terminates the selection processing (see FIG. 11).

Referring to FIG. 13, descriptions will be made. In step S31, the selection unit 205 acquires the cumulative film thickness of each process module from the history information storage unit 202. Next, the selection unit 205 generates a list of arranging each process module in ascending order of the read cumulative film thicknesses.

In step 532, the selection unit 205 initializes the index n to 1. The index n is a number indicating a sequence from a head of the list.

In step 533, the selection unit 205 determines whether an n-th process module in the list generated in step S31 is usable. In other words, the selection unit 205 determines whether the process module with an n-th smaller cumulative film thickness is usable.

When the selection unit 205 determines that the n-th process module in the list is usable (YES), the processing proceeds to step S35 by the selection unit 205. In the meantime, when the selection unit 205 determines that the n-th process module in the list is not usable (NO), the processing proceeds to step S34 by the selection unit 205.

In step S34, the selection unit 205 increments the index n, i.e., calculates n=n+1. Thereafter, the selection unit 205 returns the processing to step S33 and determines whether the n-th process module in the list is usable.

In step S35, the selection unit 205 selects the n-th process module in the list. Thereafter, the selection unit 205 terminates the selection processing (see FIG. 11).

Referring to FIG. 14, descriptions will be made. In step S41, the selection unit 205 acquires the cumulative film thickness of each process module from the history information storage unit 202. Next, the selection unit 205 generates a list of arranging each process module in descending order of the read cumulative film thicknesses.

In step S42, the selection unit 205 initializes the index n to 1. The index n is a number indicating a sequence from the head of the list.

In step S43, the selection unit 205 determines whether the n-th process module in the list generated in step S41 is usable. In other words, the selection unit 205 determines whether the process module with an n-th larger cumulative film thickness is usable.

When the selection unit 205 determines that the n-th process module in the list is usable (YES), the processing proceeds to step S45 by the selection unit 205. In the meantime, when the selection unit 205 determines that the n-th process module in the list is not usable (NO), the processing proceeds to step S44 by the selection unit 205.

In step S44, the selection unit 205 increments the index n, i.e., calculates n=n+1. Thereafter, the selection unit 205 returns the processing to step S43 and determines whether the n-th process module in the list is usable.

In step S45, the selection unit 205 selects the n-th process module in the list. Thereafter, the selection unit 205 terminates the selection processing (see FIG. 11).

Referring to FIG. 15, descriptions will be made. In step S51, the selection unit 205 acquires the number of use of each process module from the history information storage unit 202. Next, the selection unit 205 generates a list of arranging each process module in ascending order of the read numbers of use.

In step S52, the selection unit 205 initializes the index n to 1. The index n is a number indicating a sequential number from the head of the list.

In step S53, the selection unit 205 determines whether the n-th process module in the list generated in step S51 is usable. In other words, the selection unit 205 determines whether the process module with an n-th smaller number of use is usable.

When the selection unit 205 determines that the n-th process module in the list is usable (YES), the processing proceeds to step S55 by the selection unit 205. In the meantime, when the selection unit 205 determines that the n-th process module in the list is not usable (NO), the processing proceeds to step S54 by the selection unit 205.

In step S54, the selection unit 205 increments the index n, i.e., calculates n=n+1. Thereafter, the selection unit 205 returns the processing to step S53 and determines whether the n-th process module in the list is usable.

In step S55, the selection unit 205 selects the n-th process module in the list. Thereafter, the selection unit 205 terminates the selection processing (see FIG. 11).

Referring to FIG. 16, descriptions will be made. In step 561, the selection unit 205 acquires the number of use of each process module from the history information storage unit 202. Next, the selection unit 205 generates a list of arranging each process module in descending order of the read numbers of use.

In step S62, the selection unit 205 initializes the index n to 1. The index n is a number indicating a sequential number from the head of the list.

In step 563, the selection unit 205 determines whether the n-th process module in the list generated in step S61 is usable. In other words, the selection unit 205 determines whether the process module with an n-th greater number of use is usable.

When the selection unit 205 determines that the n-th process module in the list is usable (YES), the processing proceeds to step S65 by the selection unit 205. Meanwhile, when the selection unit 205 determines that the n-th process module in the list is not usable (NO), the processing proceeds to step S64 by the selection unit 205.

In step S64, the selection unit 205 increments the index n, i.e., calculates n=n+1. Then, the selection unit 205 returns the processing to step S63 and determines whether the n-th process module in the list is usable.

In step S65, the selection unit 205 selects the n-th process module in the list. Thereafter, the selection unit 205 terminates the selection processing (see FIG. 11).

Referring back to FIG. 6, descriptions will be made. In step S4, the operation unit 206 of the control apparatus 121 receives information indicating the process module selected from the selection unit 205. Next, the operation unit 206 operates the substrate processing apparatus 120 such that the processing indicated in the recipe information received in step S1 is executed in the process module selected in step S3.

When the processing terminates, the operation unit 206 stores the history information indicating the history of the processing executed in the process module, in the history information storage unit 202. Specifically, the operation unit 206 increments the number of use of the process module that has executed the processing, and adds a processed film thickness to the cumulative film thickness of the process module.

### Example of Selection Processing

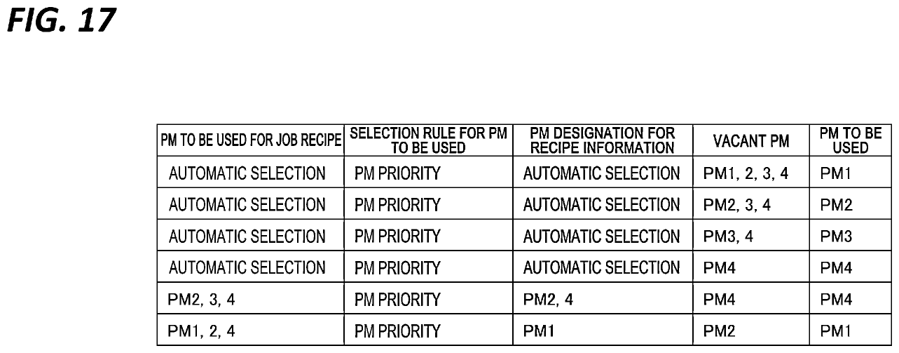

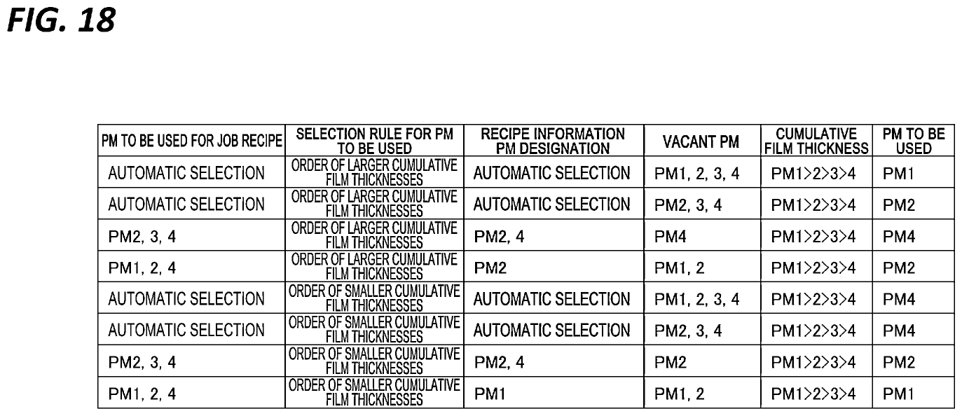

An embodiment of the selection processing in this embodiment will be described with reference to FIGS. 17 and 18. FIG. 17 is a diagram illustrating an example of a relationship between a selection processing and a process module selected when the selection rule is PM priority. FIG. 18 is a diagram illustrating an example of a relationship between a selection processing and a process module selected when the selection rule is a rule for the cumulative film thickness.

In FIGS. 17 and 18, a “PM to be used for work recipe” is a process module set as a work recipe. A “selection rule for PM to be used” (“PM selection rule”) is a selection rule set as a parameter. A “recipe information PM designation” is a process module designated as recipe information. A “vacant PM” is a usable process module. A “PM to be used” is a process module that is selected.

As illustrated in FIG. 17, when the “PM selection rule” is “PM priority”, a process module with the highest “PM priority” among the “vacant PMs” is selected. Also, when a specific process module is designated by “PM designation by recipe information”, if the process module is not usable (e.g., in the bottom row of FIG. 17, PM1 is designated, but only PM2 is vacant), the designated process module is selected, but execution of the processing is delayed until the process module becomes usable.

As illustrated in FIG. 18, when the “PM selection rule” is “the order of larger cumulative film thicknesses”, a process module with the largest cumulative film thickness among the “vacant PMs” is selected. Also, as illustrated in FIG. 18, when the “PM selection rule” is “the order of smaller cumulative film thicknesses”, a process module with the smallest cumulative film thickness among the “vacant PMs” is selected.

Although examples of cases where the “PM selection rule” is the “order of fewer numbers of use”, and the “order of greater numbers of use” are not illustrated in FIGS. 17 and 18, process modules are selected therein in the same manner as cases of the “order of smaller cumulative film thicknesses” and the “order of larger cumulative film thicknesses”.

### Effect of Embodiments

The control apparatus 121 in this embodiment receives an input of recipe information indicating a processing for a processing target and selects a process module to execute the processing based on a selection rule designated by a user. The user only needs to set a desired selection rule and performs an operation that instructs automatic selection from the recipe information. Thus, according to this embodiment, it is possible to easily select a process module desired by a user.

The selection rule in this embodiment may be a rule for designating the priority of each process module, or a rule for the use state of each process module. The use state may include the number of times processing targets are processed by the process modules or a cumulative value of the film thickness of the processing target processed by the process module. Thus, according to this embodiment, a process module may be appropriately selected based on various criterions.

The process module in this embodiment may include a processing container that receives a plurality of processing targets to perform a processing, or a processing container that receives a single processing target to perform a processing. The processing may include heat treatment such as a film formation processing or an etching processing. Therefore, according to the embodiment, it is possible to appropriately select a process module that executes various processings.

The substrate processing apparatus for executing a process including the substrate processing method of the present disclosure is not limited to a heat treatment apparatus. The substrate processing apparatus may be applied to any type of apparatuses, such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, and a helicon wave plasma (HWP) apparatus.

In addition, the substrate processing apparatus of the present disclosure may be applied to any of an apparatus using plasma and an apparatus without using plasma, as long as the substrate processing apparatus is an apparatus that performs a predetermined processing (e.g., a film formation processing or an etching processing) on the substrate. Furthermore, the substrate processing apparatus of the present disclosure may be applied to any of a single-substrate processing apparatus that processes substrates one by one, a batch apparatus that processes a plurality of substrates at once, and a semi-batch apparatus that processes, at once, a smaller number of substrates than the number of substrates processed by the batch apparatus.

According to one aspect, it is possible to easily select a process module desired by a user.

From the foregoing content, it will be appreciated that various embodiments of the present disclosure have been described herein for purposes of illustration, and that various modifications can be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a plurality of process modules each configured to process a processing target; and
a controller,
wherein the controller is configured to:
receive an input of recipe information indicating a processing for the processing target; and
select a process module for processing the processing target based on a selection rule designated by a user.

2. The substrate processing apparatus according to claim 1, wherein the selection rule is a rule that determines priority of each of the plurality of process modules.

3. The substrate processing apparatus according to claim 1, wherein the selection rule is a rule regarding a use state of each of the plurality of process modules.

4. The substrate processing apparatus according to claim 3, wherein the use state includes a number of times the processing target has been processed by each of the plurality of process modules.

5. The substrate processing apparatus according to claim 3, wherein the use state includes a cumulative value of a film thickness of the processing target processed in each of the plurality of process modules.

6. The substrate processing apparatus according to claim 1, wherein each of the plurality of process modules includes a processing container that accommodates a plurality of processing targets to perform the processing.

7. The substrate processing apparatus according to claim 1, wherein each of the plurality of process modules includes a processing container that accommodates one processing target to perform the processing.

8. The substrate processing apparatus according to claim 6, wherein the processing includes a film formation processing or an etching processing.

9. A substrate processing method comprising:
receiving an input of recipe information indicating a processing for a processing target by a substrate processing apparatus including a plurality of process modules; and
selecting a process module to process the processing target based on a selection rule designated by a user.

10. A non-transitory computer-readable storage medium having stored therein a program that causes a controller of a substrate processing apparatus including a plurality of process modules that process a processing target, to execute a process including:
receiving an input of recipe information indicating a processing for the processing target; and
selecting the process module to process the processing target based on a selection rule designated by a user.
